(19) United States
(12) Patent Application Publication
(10) Pub. No.: US 2025/0019176 A1
(43) Pub. Date: Jan. 16, 2025

(54) Article Transport Facility

(71) Applicant: Daifuku Co., Ltd., Osaka-shi (JP)

(72) Inventors: Makoto Kono, Komaki-shi (JP); Keisuke Takeno, Komaki-shi (JP); Kazuhiro Iwamitsu, Komaki-shi (JP)

(21) Appl. No.: 18/769,777

(22) Filed: Jul. 11, 2024

(30) Foreign Application Priority Data
Jul. 12, 2023 (JP) 2023-114685

(51) Int. Cl. B65G 17/12; B65G 43/00

(52) U.S. Cl. CPC B65G 17/12; B65G 43/00

(57) ABSTRACT

An article transport facility includes a control system that controls a plurality of transport vehicles. The control system performs subsequent-vehicle prioritization if a subsequent transport vehicle is proceeding to a second post-branching section different from a first post-branching section. The subsequent-vehicle prioritization is a process of causing a target transport vehicle proceeding to the first post-branching section to change a course and proceed to a post-branching section different from the first post-branching section to allow the subsequent transport vehicle to proceed to the second post-branching section.

### CROSS-REFERENCE TO RELATED APPLICATION

This application claims priority to Japanese Patent Application No. 2023-114685 filed Jul. 12, 2023, the disclosure of which is hereby incorporated by reference in its entirety.

### BACKGROUND OF THE INVENTION

### Field of the Invention

The present invention relates to an article transport facility including multiple transport vehicles that travel along a travel path.

### Description of Related Art

An example article transport facility is described in Japanese Unexamined Patent Application Publication No. 2018-128914 (Patent Literature 1). In the background described hereafter, reference signs in parentheses are the reference signs in Patent Literature 1. In the article transport facility in Patent Literature 1, a first stop position (P3) is set upstream from a branch position (P1). A transport vehicle (3) that arrives at the first stop position (P3) is stopped at the first stop position (P3) until the transport vehicle (3) is permitted to pass the branch position (P1). When the transport vehicle (3) is stopped at the first stop position (P3), a subsequent transport vehicle (3A) stops at an upstream position away from the preceding transport vehicle (3) by a preset distance.

In the state shown in FIG. 15 in Patent Literature 1, the subsequent transport vehicle is blocked by the preceding transport vehicle that is stopped at the first stop position and cannot proceed when the subsequent transport vehicle is to proceed to a post-branching section different from a post-branching section to which the transport vehicle stopped at the first stop position is to proceed. When a preceding transport vehicle is stopped at the first stop position in a situation, such as traffic congestion, in which transport vehicles cannot travel smoothly in one of multiple post-branching sections, a subsequent transport vehicle cannot proceed until the situation is resolved, thus decreasing the article transport efficiency of the entire article transport facility.

### SUMMARY OF THE INVENTION

An article transport facility is to have the article transport efficiency of the entire article transport facility that is less likely to decrease in a situation in which transport vehicles cannot travel smoothly in one of the multiple post-branching sections.

An article transport facility according to an aspect of the disclosure includes a plurality of transport vehicles that travel along a travel path to transport articles, and a control system that controls the plurality of transport vehicles. The plurality of transport vehicles include a target transport vehicle and at least one subsequent transport vehicle subsequent to the target vehicle. The travel path includes a branch at which a pre-branching section of the travel path branches into a plurality of post-branching sections of the travel path. The plurality of post-branching sections include a first post-branching section and a second post-branching section. The second post-branching section is different from the first post-branching section. The control system performs subsequent-vehicle prioritization if the plurality of transport vehicles satisfy a condition that the target transport vehicle proceeding to the first post-branching section is expected to stop in the pre-branching section based on traffic in the first post-branching section and the at least one subsequent transport vehicle is proceeding to the second post-branching section. The subsequent-vehicle prioritization is a process of causing the target transport vehicle to change a course and proceed to a post-branching section different from the first post-branching section and included in the plurality of post-branching sections to allow the at least one subsequent transport vehicle to travel into the second post-branching section.

This structure causes, when the target transport vehicle cannot proceed to the first post-branching section being the original course, the target transport vehicle to proceed to the post-branching section different from the first post-branching section for the subsequent vehicle to proceed to the second post-branching section promptly without the target transport vehicle stopped in the pre-branching section or with the target transport vehicle stopped in the pre-branching section for a shorter time. The article transport efficiency of the entire article transport facility is thus less likely to decrease in the situation in which the transport vehicles cannot travel smoothly in one of the multiple post-branching sections.

### BRIEF DESCRIPTION OF THE DRAWINGS

FIG. 1 is a diagram of an example transport facility.

FIG. 2 is a diagram of an example of transport vehicles in FIG. 1.

FIG. 3 is a diagram of one of the transport vehicles in FIG. 1 proceeding to a first post-branching section.

FIG. 4 is a diagram of one of the transport vehicles in FIG. 1 proceeding to a second post-branching section.

FIG. 5 is a diagram showing an example of subsequent-vehicle prioritization performed by a control system in FIG. 1.

### DESCRIPTION OF THE INVENTION

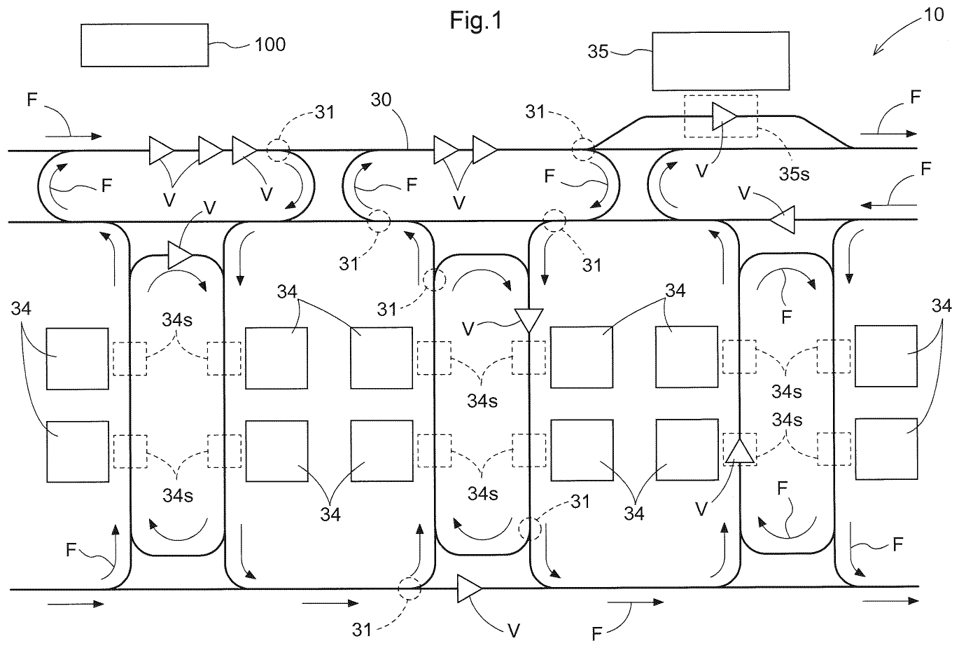

A transport facility according to an embodiment will be described with reference to the drawings. As shown in a simplified manner in FIG. 1, an article transport facility 10 includes one or more transport vehicles V that each travel along a travel path 30 to transport an article W. In the present embodiment, the article transport facility 10 includes multiple transport vehicles V. The travel path 30 refers to the entire path along which the transport vehicles V travel. The travel path 30 is a set of multiple paths (partial paths).

The article transport facility 10 includes a control system 100 that controls the transport vehicles V. The functions of the control system 100 are implemented by, for example, hardware such as an arithmetic processor and a program executable on the hardware operating in cooperation with each other. The control system 100 may be entirely located in the transport vehicles V, or may be partially located in the transport vehicles V and partially located in an external control device (a control device that is external to the transport vehicles V and can communicate with the transport vehicles V). The control system 100 may be entirely located in the external control device. The external control device may be a set of multiple devices that can communicate with one another, rather than a single device. The control system 100 controls travel of the multiple transport vehicles V to allow each transport vehicle V to reach a destination. Examples of the destination of a transport vehicle include a station of a sender and a station of a destination described later.

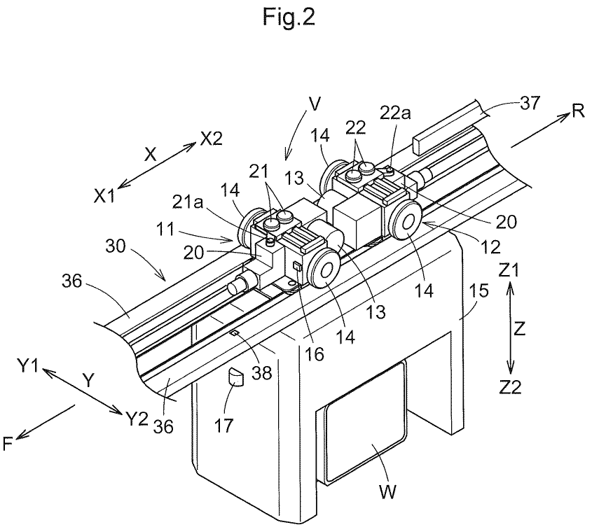

FIG. 2 is a diagram of an example of the transport vehicles V. Each transport vehicle V includes a controller (device controller) that controls travel wheel drivers 13 and guide drivers 20 described later. When the control system 100 is at least partially located in the external control device, the controller in each transport vehicle V operates in response to a command from the external control device. When the control system 100 is at least partially located in the transport vehicles V, the controller in each transport vehicle V may include at least a part of the control system 100.

As shown in FIG. 2, the direction along the travel path 30 is referred to as a travel direction X, and the direction perpendicular to the travel direction X (the horizontal direction perpendicular to the travel direction X in this example) as viewed in a vertical direction Z (the vertical direction) is referred to as a width direction Y. As shown in FIG. 1, a forward direction F is defined for various parts of the travel path 30. The direction opposite to the forward direction F is referred to as a reverse direction R (refer to FIG. 2). The transport vehicles V basically travel along the travel path 30 in the forward direction F. In the present embodiment, the travel path 30 is designed to allow each transport vehicle V to move between a sender of the article W and a destination of the article W in a circular manner while each transport vehicle Vis traveling in the forward direction F.

As shown in FIG. 2, the travel path 30 extends in the forward direction F toward a downstream end X1 and in the reverse direction R toward an upstream end X2. The travel direction X is, in other words, the front-rear direction for a transport vehicle V, the downstream end X1 is, in other words, a front direction for the transport vehicle V, and the upstream end X2 is, in other words, a rear direction for the transport vehicle V. The width direction Y includes a first width direction Y1 (the right as viewed in the forward direction F in this example) and a second width direction Y2 opposite to the first width direction Y1 (the left as viewed in the forward direction F).

The transport vehicles V travel along the travel path 30 to transport the articles W. The articles W are, for example, front opening unified pods (FOUPs) that contain semiconductor wafers. The transport vehicles V are automated guided vehicles. The travel path 30 may be a physical path or an imaginary path. In the present embodiment, the travel path 30 is a physical path including travel rails 36 (a pair of travel rails 36 spaced from each other in the width direction Y in this example). The travel rails 36 are, for example, hung from the ceiling.

Although the travel path 30 is located along the ceiling in FIG. 2, the travel path 30 may be located on, for example, the floor surface. For the travel path 30 located on the floor surface, for example, the travel path 30 is a physical path including rails on the floor surface or an imaginary path including two-dimensional (2D) codes or radio-frequency (RF) tags on the floor surface. The floor surface may be hung from the ceiling.

As shown in FIG. 2, each transport vehicle V includes a first traveler 11 as a traveler. The first traveler 11 includes travel wheels 14 that roll on travel surfaces (surfaces facing in an upper direction Z1 in this example) of the travel rails 36, and a travel wheel driver 13 (e.g., an electric motor such as a servomotor) that rotates the travel wheels 14. The travel wheels 14 are driven by the travel wheel driver 13 to rotate, thus causing the first traveler 11 to travel along the travel rails 36. In the present embodiment, the transport vehicle V further includes a second traveler 12 closer to the upstream end X2 than the first traveler 11. The second traveler 12 has the same structure as the first traveler 11. The travel wheels 14 are driven by the travel wheel driver 13 to rotate, thus causing the second traveler 12 to travel along the travel rails 36.

Each transport vehicle V includes a body 15 connected to the first traveler 11. An article W is contained in the body 15 and transported by the transport vehicle V. In the present embodiment, the body 15 is located in a lower direction Z2 from the first traveler 11 and supported by the first traveler 11. In the present embodiment, the body 15 is connected to both the first traveler 11 and the second traveler 12. The body 15 is located in the lower direction Z2 from the first traveler 11 and the second traveler 12, and supported by the first traveler 11 and the second traveler 12.

In the example shown in FIG. 2, the transport vehicle V includes a collision avoidance sensor 17 that detects another transport vehicle V closer to the downstream end X1 than the transport vehicle V. In response to a collision avoidance sensor 17 detecting another transport vehicle V, the transport vehicle V including the collision avoidance sensor 17 decelerates or stops to avoid collision with the other transport vehicle V.

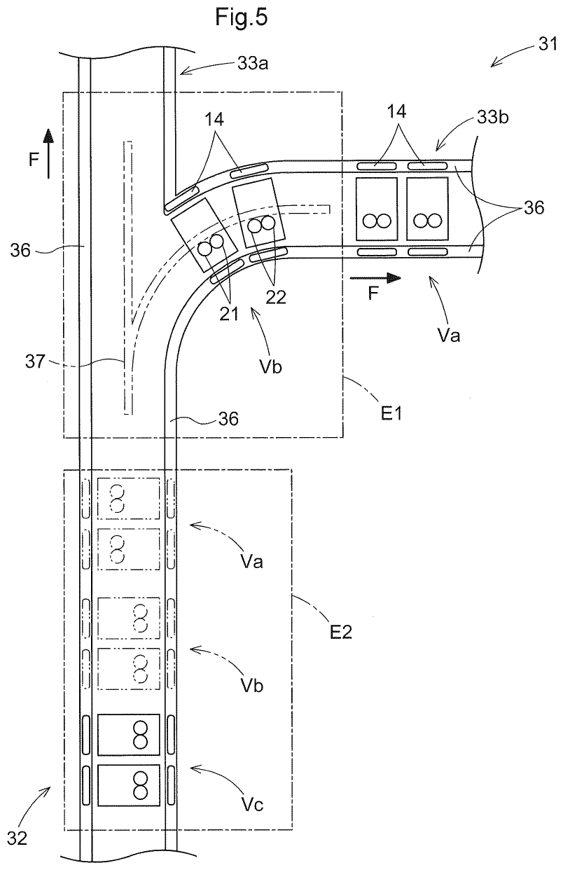

In the present embodiment, as shown in FIG. 2, information storages 38, such as 2D codes or RF tags, are at multiple locations on the travel path 30. The information storages 38 are at locations at which the transport vehicles V are possibly stopped, such as stations or branch standby areas E2 (refer to FIG. 5) described later. Each information storage 38 stores position information about the position of the information storage 38. Each transport vehicle V includes a reader 16 that reads the position information stored in the information storages 38, and identifies its current position based on the position information read by the reader 16. The transport vehicle V identifies its current position based on, for example, the position information read by the reader 16 and a travel distance after the reader 16 reads the position information. The travel distance of the transport vehicle Vis measured using, for example, a rotary encoder. The transport vehicle V may identify its current position based on an output from a positioning device such as a global navigation satellite system (GNSS) receiver.

The control system 100 tracks the current position of each of the multiple transport vehicles V. In the present embodiment, the transport vehicles V identify their current positions as described above. The control system 100 obtains, from each transport vehicle V, information about the current position of the transport vehicle V to track the current position of each of the multiple transport vehicles V.

Multiple stations serving as destinations of the transport vehicles V are located on the travel path 30. At a station, each transport vehicle V transfers an article W to or from an article support at the station. The operations of the transport vehicle V include traveling along the travel path 30, receiving an article W from the article support at a station, and transferring an article W onto the article support at a station. The transport vehicle V travels to the station of a sender, receives an article W at the station of the sender, travels to the station of a destination, and transfers the article W at the station of the destination.

Examples of the article support include a loading port in a processing device 34, a loading and unloading port in a storage device 35, and a storage shelf (not shown) that temporarily stores the articles W. The article support is located, for example, directly below the travel path 30 at each station.

The destinations of the transport vehicles V described above include processing device stations 34s at which the articles W are transferred from or to the respective processing devices 34 that process the articles W (shown in FIG. 1). The destinations of the transport vehicles V include a storage device station 35s at which the articles W are transferred from or to the storage device 35 that stores the articles W (shown in FIG. 1). The destinations of the transport vehicles V may include a maintenance station (not shown) for the transport vehicles V.

As shown in FIG. 2, the travel path 30 includes guide rails 37 in some sections of the travel path 30. In the present embodiment, the guide rails 37 are located in the upper direction Z1 from the travel rails 36. In the present embodiment, each guide rail 37 is located between, in the width direction Y, the pair of travel rails 36 spaced from each other in the width direction Y as viewed in the vertical direction.

Each transport vehicle V includes guided portions (21 and 22) that come in contact with either side surface of a guide rail 37 in the width direction Y to be guided by the guide rail 37, and the guide drivers 20 (e.g., solenoids or electric motors) that move the guided portions in the width direction Y. The guide drivers 20 move the guided portions in the width direction Y by, for example, driving the guided portions alone in the width direction Y or by driving the guided portions in the width direction Y together with supports supporting the guided portions.

In the present embodiment, the first traveler 11 includes first guide wheels 21 that rotate (freely rotate in this example) about axes extending in the vertical direction Z as the guided portions. The guide driver 20 in the first traveler 11 moves the first guide wheels 21 in the width direction Y. In the example shown in FIG. 2, the first traveler 11 includes two first guide wheels 21 aligned in the travel direction X. The guide driver 20 moves the support supporting the two first guide wheels 21 in the width direction Y to move the two first guide wheels 21 in the width direction Y.

In the present embodiment, the second traveler 12 includes second guide wheels 22 that rotate (freely rotate in this example) about axes extending in the vertical direction Z as the guided portions. The guide driver 20 in the second traveler 12 moves the second guide wheels 22 in the width direction Y. In the example shown in FIG. 2, the second traveler 12 includes two second guide wheels 22 aligned in the travel direction X. The guide driver 20 moves the support supporting the two second guide wheels 22 in the width direction Y to move the two second guide wheels 22 in the width direction Y. The first guide wheels 21 and the second guide wheels 22 will be hereafter referred to as guide wheels without being distinguished from each other when the features common to these guide wheels are described.

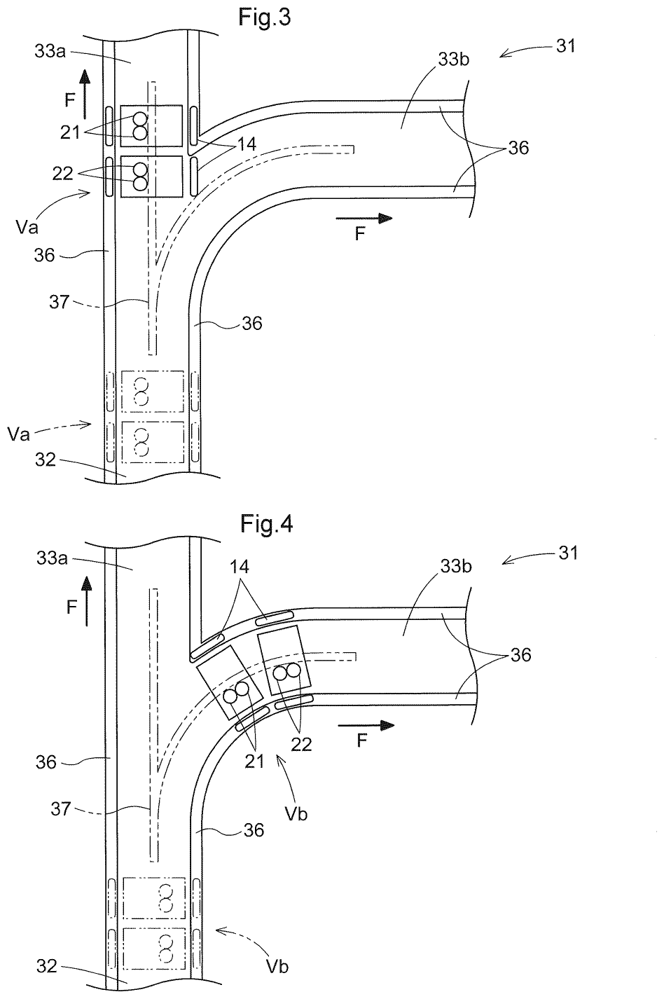

FIG. 3 is a diagram of a target transport vehicle Va, which is one of the multiple transport vehicles V, proceeding to a first post-branching section 33a. FIG. 4 is a diagram of a subsequent transport vehicle Vb, which is a transport vehicle V subsequent to the target transport vehicle Va, proceeding to a second post-branching section 33b. The travel path 30 includes branches 31 at which a pre-branching section 32 of the travel path 30 branches into multiple post-branching sections (33a and 33b) of the travel path 30. Although the branch 31 includes post-branching sections including two path sections that are the first post-branching section 33a and the second post-branching section 33b in the examples shown in FIGS. 3 and 4, the branch 31 may include three or more path sections.

The pre-branching section 32 does not include another pre-branching section 32 closer to the upstream end X2 than the corresponding branch 31. The pre-branching section 32 is preset for each branch 31. In the present embodiment, the pre-branching section 32 does not include the other pre-branching sections 32. The pre-branching section 32 includes no guide rail 37. The pre-branching section 32 includes no station described above. The pre-branching section 32 includes no junction in which multiple paths merge. The pre-branching section 32 is a straight section.

Each post-branching section (33a or 33b) does not include another post-branching section closer to the downstream end X1 than the corresponding branch 31. The post-branching section is preset for each branch 31. In the present embodiment, the post-branching section does not include the other post-branching sections. The post-branching section includes no guide rail 37. The post-branching section includes no station described above. The post-branching section includes no junction in which multiple paths merge.

The reverse direction R, the travel direction X, the downstream end X1, the upstream end X2, the width direction Y, the first width direction Y1, and the second width direction Y2 described above are defined based on the forward direction F, which is the travel direction of the paths into which each branch 31 branches. Thus, in FIGS. 3 to 5, these directions are not indicated, and the forward direction F alone is indicated.

At each branch 31, a transport vehicle V proceeds to either the first post-branching section 33a or the second post-branching section 33b based on the positions of the first guide wheels 21 and the second guide wheels 22 in the width direction Y when the transport vehicle V enters the branch 31. More specifically, when the transport vehicle V enters the branch 31 with the first guide wheels 21 and the second guide wheels 22 at the positions at which the first guide wheels 21 and the second guide wheels 22 come in contact with the guide rail 37 in the first width direction Y1, the transport vehicle V proceeds to the post-branching section (the second post-branching section 33b in the branch 31 shown in FIGS. 3 and 4) in the first width direction Y1. When the transport vehicle V enters the branch 31 with the first guide wheels 21 and the second guide wheels 22 at the positions at which the first guide wheels 21 and the second guide wheels 22 come in contact with the guide rail 37 in the second width direction Y2, the transport vehicle V proceeds to the post-branching section (the first post-branching section 33a in the branch 31 shown in FIGS. 3 and 4) in the second width direction Y2. The guide drivers 20 move the guide wheels (21 and 22) to the positions in the width direction Y corresponding to the branch path to which the transport vehicle V proceeds before the transport vehicle V enters the branch 31.

In the present embodiment, each transport vehicle V includes movement detectors (21a and 22a) that detect movements of the guide wheels (21 and 22) in the width direction Y. The control system 100 obtains detection results of the movements of the guide wheels in the width direction Y from the movement detectors to detect the guide wheels moving in the width direction Y.

The movement detectors (21a and 22a) detect, for example, the positions of the guide wheels (21 and 22) or the positions of the supports supporting the guide wheels in the width direction Y to detect the movements of the guide wheels in the width direction Y. The movement detectors may detect the movements of the guide wheels or the movements of the supports supporting the guide wheels to detect the movements of the guide wheels in the width direction Y. In this case, the movement detectors detect, for example, changes in the torque of the motors included in the guide drivers 20 to detect the movements of the guide wheels or the movements of the supports supporting the guide wheels.

In the present embodiment, each transport vehicle V includes, as the movement detectors (21a and 22a), a first movement detector 21a that detects movements of the first guide wheels 21 in the width direction Y and a second movement detector 22a that detects movements of the second guide wheels 22 in the width direction Y. The first movement detector 21a is included in the first traveler 11, and the second movement detector 22a is included in the second traveler 12.

In the present embodiment, as shown in FIG. 5, a branch area E1 is preset in each branch 31. When one of the multiple transport vehicles V is in the branch area E1, the control system 100 performs branch standby control to cause other transport vehicles V that are to enter the branch area E1 to stop in the branch standby area E2 in the pre-branching section 32. Although the branch area E1 does not include the branch standby area E2, the branch area E1 may include a part of the pre-branching section 32 of the corresponding branch 31 or parts of the post-branching sections (33a and 33b) of the corresponding branch 31.

In the present embodiment, multiple transport vehicles V can stop in the branch standby area E2. The branch standby area E2 may include multiple areas. The branch standby area E2 may include, for example, a branch, a post-branching section, a junction, and a curved section closer to the upstream end X2 than the corresponding branch 31. In the illustrated example, the branch standby area E2 is a straight section.

The control system 100 performs subsequent-vehicle prioritization when the target transport vehicle Va, which is one of the multiple transport vehicles V, proceeding to the first post-branching section 33a, which is one of the multiple post-branching sections (33a and 33b), is stopped in the pre-branching section 32 based on the traffic in the first post-branching section 33a and when the subsequent transport vehicle Vb, which is a subsequent transport vehicle V, is proceeding to the second post-branching section 33b, which is a post-branching section different from the first post-branching section 33a. The subsequent-vehicle prioritization is a process of causing the subsequent transport vehicle Vb to proceed to the second post-branching section 33b by causing the target transport vehicle Va to change its course and proceed to a post-branching section different from the first post-branching section 33a and included in the multiple post-branching sections.

Although the target transport vehicle Va proceeds to the second post-branching section 33b in the subsequent-vehicle prioritization in the example described below, for the branch 31 including three or more post-branching sections, the target transport vehicle Va may proceed to a post-branching section different from the first post-branching section 33a or the second post-branching section 33b. Although the target transport vehicle Va is stopped in the pre-branching section 32 and the subsequent-vehicle prioritization is performed in the example described below, the subsequent-vehicle prioritization may be performed to cause the target transport vehicle Va to proceed to the second post-branching section 33b without being stopped in the pre-branching section 32.

Examples of the traffic described above that cause the target transport vehicle Va to stop in the pre-branching section 32 include traffic congestion, traveling or stopping of a transport vehicle V with a failure, a processing device station 34s being full, the storage device station 35s being full, an abnormality in the travel rail 36, an abnormality in a processing device 34, an abnormality in the storage device 35, and a situation that obstructs traffic of the transport vehicles V. The determination as to whether the traffic is congested is performed by the control system 100 based on, for example, the number of transport vehicles Vin, for example, the post-branching sections (33a and 33b), a preset section at the downstream end X1 than the post-branching sections, a preset section closer to the downstream end X1 than the post-branching sections, the pre-branching section 32 closer to the downstream end X1 than the post-branching sections, the post-branching sections closer to the downstream end X1 than the post-branching sections, or the stations described above.

In FIG. 5, the control system 100 causes the subsequent transport vehicle Vb to proceed to the second post-branching section 33b by causing the target transport vehicle Va of the three transport vehicles V (Va, Vb, and Vc) that are stopped in the branch standby area E2 to change the course and proceed to the second post-branching section 33b. When the transport vehicle Vc is to proceed to the second post-branching section 33b, the control system 100 causes the transport vehicle Vc to proceed to the second post-branching section 33b after the subsequent transport vehicle Vb proceeds to the second post-branching section 33b. When the transport vehicle Vc is to proceed to the first post-branching section 33a, the control system 100 causes the transport vehicle Vc to stop at the front in the branch standby area E2. The transport vehicle Vc is then the next target transport vehicle Va. The control system 100 may not cause the transport vehicle Vc to stop at the front in the branch standby area E2 when the issue caused in the first post-branching section 33a is already resolved.

Hereafter, N is an integer greater than or equal to 2. The control system 100 performs the subsequent-vehicle prioritization further when N or more transport vehicles V are subsequent to the target transport vehicle Va. Examples of the subsequent transport vehicles V include transport vehicles V stopped in the branch standby area E2 excluding the target transport vehicle Va, transport vehicles V stopped in or traveling through the branch standby area E2 excluding the target transport vehicle Va, and transport vehicles V stopped in or traveling through the pre-branching section 32 excluding the target transport vehicle Va.

Examples of the condition indicated by “further when N or more transport vehicles V are subsequent to the target transport vehicle Va” include the number of subsequent transport vehicles V being the upper limit of the vehicles that can be stopped in the branch standby area E2, the number of subsequent transport vehicles V being a preset number of vehicles that is a half or more of the vehicles that can be stopped in the branch standby area E2 and less than the upper limit of the vehicles that can be stopped, the number of subsequent transport vehicles V stopped in the branch standby area E2 being greater than or equal to 2, or greater than or equal to 3, and the number of subsequent transport vehicles V in the pre-branching section 32 being greater than or equal to 2, or greater than or equal to 3. The control system 100 may perform the subsequent-vehicle prioritization further when N or more transport vehicles V (N is an integer greater than or equal to 2) are to proceed to a post-branching section (the second post-branching section 33b in the example shown in FIG. 5) different from the first post-branching section 33a.

The control system 100 performs the subsequent-vehicle prioritization further when the destination of the subsequent transport vehicle Vb is a processing device station 34s. The control system 100 may perform the subsequent-vehicle prioritization further when the destination of one of the transport vehicles V subsequent to the target transport vehicle Va is a processing device station 34s. The control system 100 may perform the subsequent-vehicle prioritization further when the processing device station 34s as the destination is not full, or may perform the subsequent-vehicle prioritization irrespective of whether the processing device station 34s as the destination is full.

The transport vehicles V that are not transporting the articles W are referred to as empty transport vehicles. The transport vehicles V that are transporting the articles W are referred to as loaded transport vehicles. The control system 100 may perform the subsequent-vehicle prioritization further when one of the transport vehicles V subsequent to the target transport vehicle Va is an empty transport vehicle. The control system 100 may perform the subsequent-vehicle prioritization further when empty transport vehicles among the transport vehicles V subsequent to the target transport vehicle Va include N or more transport vehicles (N is an integer greater than or equal to 2). The control system 100 may perform the subsequent-vehicle prioritization further when one of the transport vehicles V subsequent to the target transport vehicle Va is a loaded transport vehicle. The control system 100 may perform the subsequent-vehicle prioritization further when loaded transport vehicles among the transport vehicles V subsequent to the target transport vehicle Va include N or more transport vehicles (N is an integer greater than or equal to 2).

The control system 100 performs the subsequent-vehicle prioritization further when the target transport vehicle Va is stopped in the pre-branching section 32 for a period longer than or equal to a preset determination period. Examples of the period during which the target transport vehicle Va is stopped in the pre-branching section 32 include the period during which the target transport vehicle Va is stopped at the front in the branch standby area E2 and the period during which the target transport vehicle Va is stopped at the front and a position other than the front in the branch standby area E2.

The subsequent-vehicle prioritization may be performed further when the destination of the target transport vehicle Va is reachable through the second post-branching section 33b. Examples of being reachable include the destination being reachable without traveling in the reverse direction R, the destination being reachable without traveling through a section in which the transport vehicles V cannot travel, the destination being reachable without traveling through a section including a transport vehicle V with a failure, the destination being reachable without traveling through a section with an abnormality in the travel rails 36, the destination being reachable without traveling through a section with traffic congestion, and the destination being reachable without returning to the branch 31.

The subsequent-vehicle prioritization may be performed further when the destination of the target transport vehicle Va is unreachable through the second post-branching section 33b and when the target transport vehicle Va can retract to a retraction section (not shown) in a post-branching section different from the first post-branching section 33a. After retracting to the retraction section, the target transport vehicle Va is returned to the pre-branching section 32 by, for example, the control system 100 or a device that transports the transport vehicles V, and enters the first post-branching section 33a. In the subsequent-vehicle prioritization, the destination of the target transport vehicle Va that is to proceed to the second post-branching section 33b may be changed.

In the present embodiment, the control system 100 calculates an estimated time for the target transport vehicle Va to reach its destination, and performs the subsequent-vehicle prioritization further when an estimated time for the target transport vehicle Va to reach the destination after traveling through a post-branching section (the second post-branching section 33b in the example shown in FIG. 5) different from the first post-branching section 33a is longer than an estimated time for the target transport vehicle Va to reach the destination after traveling through the first post-branching section 33a by an amount less than or equal to a preset determination threshold.

The above estimated time is calculated based on, for example, a path cost determined based on the distance from the branch 31 to the destination and travel conditions of the target transport vehicle Va. The path cost is calculated by, for example, Dijkstra's algorithm. The above estimated time may be calculated using, for example, past statistical information.

The path cost is calculated to be higher as the distance from the branch 31 to the destination is longer. The path cost is calculated to be higher when the above travel conditions include a condition that causes the time for the transport vehicle V to travel to increase. For example, for the travel conditions including a congestion level of the path, the path cost is calculated to be higher as the congestion level of the path is higher. The congestion level of the path is calculated based on, for example, the number of transport vehicles V in a preset section.

The above travel conditions include, for example, at least one of the congestion level of the path, the structure of the path (e.g., one of a straight section, a curved section, a branch, or a junction), the number of stations on the path, or the state of the transport vehicle V (e.g., either an empty transport vehicle or a loaded transport vehicle). For example, in a section in which a maintenance lifter, which is used to lower a transport vehicle V from the travel path 30 adjacent to the ceiling to the ground for maintenance of the transport vehicle V, is connected to the travel path 30, a transport vehicle V heading to the maintenance lifter or a transport vehicle V being returned from the maintenance lifter to the travel path 30 can increase the congestion level of the section.

In the present embodiment, the path cost is a value obtained by adding section costs of all the sections included in the path from the branch 31 to the destination. The section cost of each section can be a value obtained by multiplying a base cost that is a cost based on the distance of the section by a correction coefficient determined based on the travel conditions of the transport vehicle V in the section. The base cost is set to be higher as the section for which the base cost is set is longer. The correction coefficient is set to be greater when the travel conditions of the transport vehicle V in the section for which the correction coefficient is set include a condition that causes the time for the transport vehicle V to pass through the section to increase. Although not described in detail, the travel path 30 can be represented using nodes and links connecting the nodes. Each node corresponds to a specific point such as a branch 31 or a junction. Each link corresponds to a portion of the path connecting specific points. In this case, the section cost described above can be a cost (link cost) of a section corresponding to each link.

An article transport facility 10 according to other embodiments will now be described.
(1) In the above embodiment, the post-branching section in the first width direction Y1 is the second post-branching section 33b, whereas the post-branching section in the second width direction Y2 is the first post-branching section 33a. In some embodiments, for example, the post-branching section in the first width direction Y1 may be the first post-branching section 33a, whereas the post-branching section in the second width direction Y2 may be the second post-branching section 33b.
(2) In the above embodiment, the subsequent-vehicle prioritization is performed further when multiple transport vehicles V are subsequent to the target transport vehicle Va. In some embodiments, the subsequent-vehicle prioritization may be performed when, for example, one transport vehicle V is subsequent to the target transport vehicle Va.
(3) In the above embodiment, the subsequent-vehicle prioritization is performed further when the target transport vehicle Va is stopped in the pre-branching section 32 for a period longer than or equal to the preset determination period. In some embodiments, for example, the determination period may not be preset.
(4) In the above embodiment, the estimated time for the target transport vehicle Va to reach the destination is calculated, and the subsequent-vehicle prioritization is performed further when an increase in the estimated time for the target transport vehicle Va to reach the destination is less than or equal to the preset determination threshold. In some embodiments, for example, the estimated time for the target transport vehicle Va to reach the destination may not be calculated.
(5) In the above embodiment, the destinations of the transport vehicles V include the processing device stations 34s and the storage device station 35s. In some embodiments, for example, the destinations of the transport vehicles V may not include the storage device station 35s. For example, the destinations of the transport vehicles V may not include the processing device stations 34s.
(6) In the above embodiment, each pre-branching section 32 includes the branch standby area E2 in which multiple transport vehicles V can stop. In some embodiments, for example, the branch standby area E2 may be an area in which one transport vehicle V alone can stop. The pre-branching section 32 may not include the branch standby area E2, and may include a deceleration area in which the transport vehicles V decelerate.
(7) In the above example, the pre-branching section 32 is preset for each branch 31 and does not include the other pre-branching sections 32. In some embodiments, for example, the pre-branching section 32 may include another pre-branching section 32, a post-branching section, a station, a branch, a junction, and a curved section closer to the upstream end X2 than the pre-branching section 32. The pre-branching section 32 may be changed based on the destination of the transport vehicle V.
(8) In the above example, the post-branching sections (33a and 33b) are preset for each branch 31 and do not include any other post-branching sections. In some embodiments, for example, each post-branching section may include a pre-branching section 32, a post-branching section, a station, a branch, a junction, and a curved section closer to the downstream end X1 than the post-branching section. The post-branching section may be changed based on the destination of the transport vehicle V.
(9) The structure described in each of the above embodiments may be combined with any other structures described in the other embodiments unless any contradiction arises. This also applies to combinations of the embodiments described as other embodiments. The embodiments described herein are merely illustrative in all aspects and may be modified variously as appropriate without departing from the spirit and scope of the disclosure.

The article transport facility according to one or more embodiments of the disclosure will be described below.

In one embodiment, an article transport facility includes a plurality of transport vehicles that travel along a travel path to transport articles, and a control system that controls the plurality of transport vehicles. The plurality of transport vehicles include a target transport vehicle and at least one subsequent transport vehicle subsequent to the target vehicle. The travel path includes a branch at which a pre-branching section of the travel path branches into a plurality of post-branching sections of the travel path. The plurality of post-branching sections include a first post-branching section and a second post-branching section. The second post-branching section is different from the first post-branching section. The control system performs subsequent-vehicle prioritization if the plurality of transport vehicles satisfy a condition that the target transport vehicle proceeding to the first post-branching section is expected to stop in the pre-branching section based on traffic in the first post-branching section and the at least one subsequent transport vehicle is proceeding to the second post-branching section. The subsequent-vehicle prioritization is a process of causing the target transport vehicle to change a course and proceed to a post-branching section different from the first post-branching section and included in the plurality of post-branching sections to allow the at least one subsequent transport vehicle to travel into the second post-branching section.

This structure causes, when the target transport vehicle cannot proceed to the first post-branching section being the original course, the target transport vehicle to proceed to the post-branching section different from the first post-branching section for the subsequent vehicle to proceed to the second post-branching section promptly without the target transport vehicle stopped in the pre-branching section or with the target transport vehicle stopped in the pre-branching section for a shorter time. The article transport efficiency of the entire article transport facility is thus less likely to decrease in the situation in which the transport vehicles cannot travel smoothly in one of the multiple post-branching sections.

In one embodiment, the control system performs the subsequent-vehicle prioritization if the plurality of transport vehicles further satisfy an additional condition that the at least one subsequent transport vehicle subsequent to the target vehicle includes N or more transport vehicles, where N is an integer greater than or equal to 2.

In this structure, the determination as to whether the subsequent-vehicle prioritization is to be performed is based on the number of transport vehicles subsequent to the target transport vehicle. This allows the subsequent-vehicle prioritization to be performed appropriately based on the level of prioritization of the subsequent transport vehicles.

In one embodiment, the control system performs the subsequent-vehicle prioritization if the plurality of transport vehicles further satisfy an additional condition that the target transport vehicle has been stationary in the pre-branching section for a period longer than or equal to a preset determination period.

In this structure, the subsequent-vehicle prioritization is not performed until the target transport vehicle is stopped in the pre-branching section for the period longer than or equal to the determination period. Thus, the target transport vehicle is less likely to be diverted excessively by the subsequent-vehicle prioritization performed when the target transport vehicle is stopped in the pre-branching section for a shorter period.

In one embodiment, the control system calculates an estimated time for the target transport vehicle to reach a destination, and performs the subsequent-vehicle prioritization if the plurality of transport vehicles further satisfy an additional condition that an estimated time for the target transport vehicle to reach the destination after traveling through the post-branching section different from the first post-branching section is longer than an estimated time for the target transport vehicle to reach the destination after traveling through the first post-branching section by an amount less than or equal to a preset determination threshold.

In this structure, the subsequent-vehicle prioritization is not performed when the target transport vehicle is to reach the destination excessively late by proceeding to a post-branching section different from the first post-branching section. This reduces a decrease in the article transport efficiency caused by diversion of the target transport vehicle.

In one embodiment, a destination of the plurality of transport vehicles includes a processing device station, at which the articles are transferred from or to a processing device that processes the articles, and a storage device station, at which the articles are transferred from or to a storage device that stores the articles. The control system performs the subsequent-vehicle prioritization if the plurality of transport vehicles further satisfy an additional condition that the destination of the at least one subsequent transport vehicle is the processing device station.

For the processing device to perform processing efficiently, an article is to be transferred from or to the processing device at an appropriate timing. In contrast, the storage device simply stores the articles, and thus timing deviation of transporting the articles to the storage device may be tolerated. In this structure, the subsequent-vehicle prioritization is performed when the destination of the subsequent transport vehicle is the processing device station. This easily allows an article to be transferred from or to the processing device at an appropriate timing.

The article transport facility according to one or more embodiments of the disclosure may produce at least one of the effects described above.

The technical features of the article transport facility according to one or more embodiments of the disclosure are applicable to a control method for a transport vehicle and a control program for a transport vehicle.

What is claimed is:

1. An article transport facility, comprising:
a plurality of transport vehicles configured to travel along a travel path to transport articles, the plurality of transport vehicles comprising a target transport vehicle and at least one subsequent transport vehicle subsequent to the target vehicle; and
a control system configured to control the plurality of transport vehicles, and
wherein:
the travel path comprises a branch at which a pre-branching section of the travel path branches into a plurality of post-branching sections of the travel path, the plurality of post-branching sections comprising a first post-branching section and a second post-branching section, the second post-branching section being different from the first post-branching section, and
the control system is configured to perform subsequent-vehicle prioritization if the plurality of transport vehicles satisfy a condition that the target transport vehicle proceeding to the first post-branching section is expected to stop in the pre-branching section based on traffic in the first post-branching section and the at least one subsequent transport vehicle is proceeding to the second post-branching section, the subsequent-vehicle prioritization being a process of causing the target transport vehicle to change a course and proceed to a post-branching section different from the first post-branching section and included in the plurality of post-branching sections to allow the at least one subsequent transport vehicle to travel into the second post-branching section.

2. The article transport facility according to claim 1, wherein:
the control system performs the subsequent-vehicle prioritization if the plurality of transport vehicles further satisfy an additional condition that the at least one subsequent transport vehicle subsequent to the target vehicle comprises N or more transport vehicles, where N is an integer greater than or equal to 2.

3. The article transport facility according to claim 1, wherein:
the control system performs the subsequent-vehicle prioritization if the plurality of transport vehicles further satisfy an additional condition that the target transport vehicle has been stationary in the pre-branching section for a period longer than or equal to a preset determination period.

4. The article transport facility according to claim 1, wherein:
the control system calculates an estimated time for the target transport vehicle to reach a destination, and performs the subsequent-vehicle prioritization if the plurality of transport vehicles further satisfy an additional condition that an estimated time for the target transport vehicle to reach the destination after traveling through the post-branching section different from the first post-branching section is longer than an estimated time for the target transport vehicle to reach the destination after traveling through the first post-branching section by an amount less than or equal to a preset determination threshold.

5. The article transport facility according to claim 1, wherein:
a destination of the plurality of transport vehicles comprises:
a processing device station, at which the articles are transferred from or to a processing device configured to process the articles, and
a storage device station, at which the articles are transferred from or to a storage device configured to store the articles, and
the control system performs the subsequent-vehicle prioritization if the plurality of transport vehicles further satisfy an additional condition that the destination of the at least one subsequent transport vehicle is the processing device station.
